(19) United States
(12) Patent Application Publication
(10) Pub. No.: US 2017/0054013 A1
(43) Pub. Date: Feb. 23, 2017

(54) SEMICONDUCTOR DEVICE

(71) Applicant: Kabushiki Kaisha Toshiba, Minato-ku (JP)

(72) Inventor: Keiichi MATSUSHITA, Ota (JP)

(73) Assignee: Kabushiki Kaisha Toshiba, Minato-ku (JP)

(21) Appl. No.: 15/230,557

(22) Filed: Aug. 8, 2016

(30) Foreign Application Priority Data
Aug. 20, 2015 (JP) 2015-162585

(51) Int. Cl. H01L 29/778; H01L 23/31; H01L 29/20

(52) U.S. Cl. CPC H01L 29/778; H01L 29/2003; H01L 23/3171

(57) ABSTRACT

A semiconductor device includes a substrate; a first nitride semiconductor layer formed on the substrate, a second nitride semiconductor layer formed on the first nitride semiconductor layer and containing gallium element; and a third nitride semiconductor layer formed on the second nitride semiconductor layer and containing indium element, aluminum element, and gallium element, in which the composition ratio of the gallium element of the third nitride semiconductor layer is a proportion smaller than that of the second nitride semiconductor layer.

### CROSS-REFERENCE TO RELATED APPLICATIONS

This application is based upon and claims the benefit of priority from Japanese Patent Application No. 2015-162585, filed on Aug. 20, 2015, the entire contents of which are incorporated herein by reference.

### FIELD

Embodiments described herein relate generally to a semiconductor device.

### BACKGROUND

In high-power semiconductor devices used in communication devices and the like, nitride semiconductors using gallium nitride (GaN) are used. Regarding high-power semiconductor devices, there is known a semiconductor device having a HEMT structure, in which a layer of gallium nitride (GaN layer) is formed, and a layer of aluminum gallium nitride (AlGaN layer) containing aluminum element (Al) is formed thereon. In conventional semiconductor devices, adhesion of impurities onto the AlGaN layer is suppressed by further forming a GaN layer as a cap layer on the AlGaN layer, and the surface state of the semiconductor devices is stabilized.

However, when a GaN layer is used as a cap layer, in a case in which a passivation layer such as a nitride film is covered thereon, gallium element (Ga) binds with the oxygen element (O) or water molecule (H₂O) included in the passivation layer and thereby produces impurities such as GaO. GaO generates current collapse or the like in the vicinity of the gate electrode of a semiconductor device, and there is a problem that the characteristics of the semiconductor device are deteriorated, and a decrease in the service life is brought about.

### BRIEF DESCRIPTION OF THE DRAWINGS

FIG. 1 is a cross-sectional diagram of a semiconductor device according to a first embodiment;

FIG. 2 is a correlation diagram between the lattice constant and the band gap of a nitride semiconductor; and

FIG. 3 is a correlation diagram between the lattice constant and the band gap of nitride semiconductor AlGaN.

### DETAILED DESCRIPTION

According to one embodiment, a semiconductor device includes a substrate; a first nitride semiconductor layer formed on the substrate, a second nitride semiconductor layer formed on the first nitride semiconductor layer and containing gallium element; and a third nitride semiconductor layer formed on the second nitride semiconductor layer and containing indium element, aluminum element, and gallium element, in which the composition ratio of the gallium element of the third nitride semiconductor layer is a proportion smaller than that of the second nitride semiconductor layer.

Embodiments of the invention will now be described with reference to the drawings.

### First Embodiment

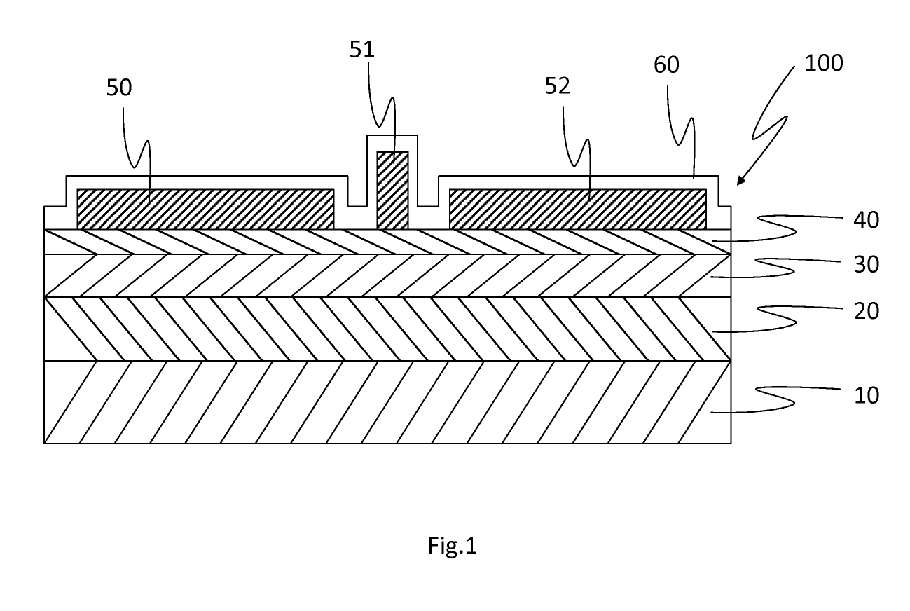

FIG. 1 is a cross-sectional diagram of a semiconductor device 100, which is a first embodiment.

A gallium nitride layer (GaN layer, first nitride semiconductor layer) 20 as a channel layer is formed on a substrate 10. Formed on the gallium nitride layer 20 is an aluminum gallium nitride layer (AlGaN layer, second nitride semiconductor layer) 30 as a barrier layer. Furthermore, an indium aluminum gallium nitride layer (InAlGaN layer, third nitride semiconductor layer) 40 as a cap layer is formed on the aluminum gallium nitride layer 30.

On the indium aluminum gallium nitride layer 40, a source electrode 50, a gate electrode 51, and a drain electrode 52 are provided. The source electrode 50, the gate electrode 51, and the drain electrode 52 are provided so as to be respectively separated apart from one another. The source electrode 50 and the drain electrode 52 are provided so as to have the gate electrode 51 interposed therebetween.

On the indium aluminum gallium nitride layer 40, source electrode 50, gate electrode 51, and drain electrode 52, a passivation layer 60 is provided.

Examples of the member of the substrate 10 include silicon (Si), silicon carbide (SiC), sapphire, gallium nitride (GaN), and diamond. However, according to the present embodiment, the member of the substrate 10 is not intended to be limited to these.

The gallium nitride layer 20, the aluminum gallium nitride layer 30, and the indium aluminum gallium nitride layer 40 are formed from nitride semiconductors. According to the present embodiment, these layers are formed from Group III-V semiconductors obtained by combining the elements of Group III, such as aluminum (Al), gallium (Ga) and indium (In), with nitrogen (N), which is an element of Group V.

GaN has a wider band gap compared to Si, and has excellent voltage resistance. Therefore, GaN is used in power devices for high-power use, to which high voltage can be applied. Furthermore, since the saturation electron velocity of GaN is higher than that of Si, and the electron mobility of GaN is equivalent to that of Si, GaN is also used in high-frequency semiconductor devices for microwaves.

The gallium nitride layer 20 (first nitride semiconductor layer) and the aluminum gallium nitride layer 30 (second nitride semiconductor layer) are formed by combining those nitrides having lattice constants that are close to each other.

The gallium nitride layer 20 and the aluminum gallium nitride layer 30 respectively have different band gaps. When the gallium nitride layer 20 and the aluminum gallium nitride layer 30 are joined, quantum wells of energy levels are formed in the vicinity of the joining surface (heterogeneous interface), and electrons are accumulated in the quantum wells at a high density. Thus, a two-dimensional electron gas (2DEG) is formed.

The indium aluminum gallium nitride layer 40 is a cap layer of the semiconductor device 100. The indium aluminum gallium nitride layer 40 covers the upper end of the aluminum gallium nitride layer 30 and terminates the dangling bonds at the surface of the relevant layer. That is, the indium aluminum gallium nitride layer 40 prevents the formation of trap levels on the surface of the aluminum gallium nitride layer 30 and suppresses deterioration of the characteristics of the semiconductor device 100.

The source electrode 50 and the drain electrode 52 are provided on the indium aluminum gallium nitride layer 40 by Ohmic contact. The gate electrode 51 is provided on the indium aluminum gallium nitride layer 40 by Schottky contact.

The passivation layer 60 is constructed from a nitride film or the like, and the nitride film is formed from silicon nitride (SiN) or the like. The passivation layer 60 has a role of protecting the various electrodes from water molecule or the like by covering the various electrodes.

SiN may contain oxygen element (O), and as the oxygen element (O) and the gallium element (Ga) in the cap layer bond together, impurities (GaO) are generated on the cap layer surface. Since a GaN layer has been hitherto used as the cap layer of the semiconductor device 100, and SiN has been used thereon as a passivation layer 60, a large quantity of impurities (GaO) is generated.

When a large amount of the impurities (GaO) is generated at the interface between the cap layer and the passivation layer 60, energy levels are formed at the relevant interface, and the effect of current collapse is increased.

The semiconductor device 100 of the present embodiment uses an indium aluminum gallium nitride layer 40 in which the content of the gallium element (Ga) in the cap layer has been replaced with indium element (In). Thereby, the content of the gallium element (Ga) in the cap layer is decreased, and therefore, the formation of the impurities (GaO) generated at the interface between the cap layer and the passivation layer 60 can be suppressed. Thereby, the influence exerted by current collapse or the like caused by the impurities (GaO) can be suppressed.

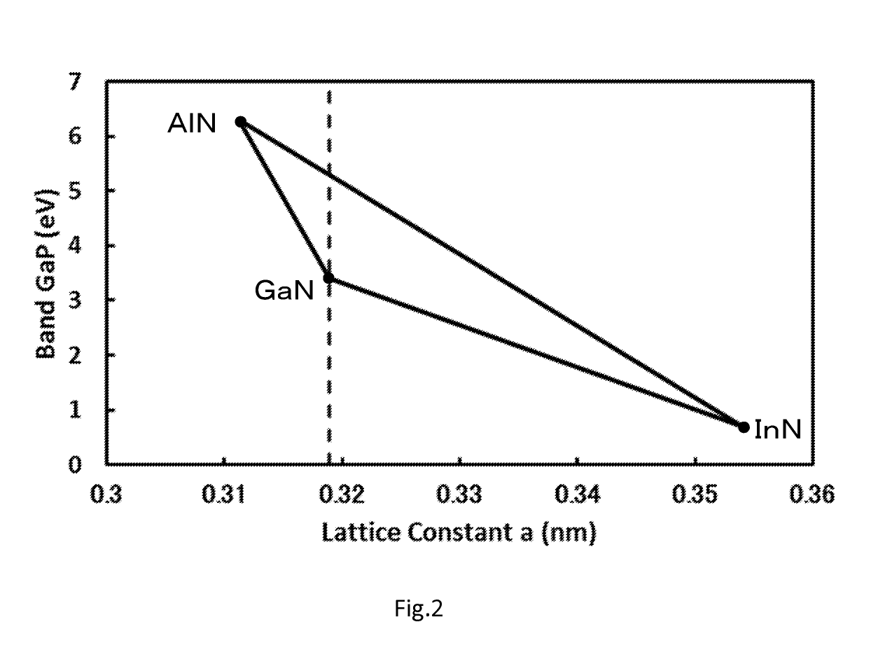

FIG. 2 is a correlation diagram between the lattice constant and the band gap of a nitride semiconductor. The respective values of the lattice constant and the respective values of the band gap of GaN, AlN, and InN are plotted, and the plots are connected by line segments. The broken line represents the value of the lattice constant of GaN.

The line that connects GaN with AlN represents the characteristics of Al_{y}Ga_{1-y}N. y represents the composition ratio of aluminum element (Al), and the following relationship is established: 0≦y≦1. That is, when the composition ratio of the aluminum element (Al) is increased, and the composition ratio of the gallium element (Ga) is decreased, the composition becomes close to AlN, and the difference in the lattice constant between Al_{y}Ga_{1-y}N and GaN becomes larger. Thereby, consistency in the lattice constant between Al_{y}Ga_{1-y}N and GaN is lost.

The line that connects GaN with InN represents the characteristics of InₓGa₁₋ₓN. x represents the composition ratio of indium element (In), and the following relationship is established: 0≦x≦1. That is, when the composition ratio of the indium element (In) is increased, and the composition ratio of the gallium element (Ga) is decreased, the composition becomes close to InN, and the difference in the lattice constant between InₓGa₁₋ₓN and GaN becomes larger. Thereby, consistency in the lattice constant between InₓGa₁₋ₓN and GaN is lost.

The composition of the indium aluminum gallium nitride layer 40 of the semiconductor device 100 of the present embodiment is defined as InₓAl_{y}Ga_{1-z-y}N (0≦x≦1, 0≦y≦1). InₓAl_{y}Ga_{1-x-y}N is positioned within a triangle obtained by connecting the respective plots of GaN, AlN, and InN in FIG. 2.

The composition ratio of gallium element (Ga) in the aluminum gallium nitride layer 30 (second nitride semiconductor layer, AlGaN layer) is about 80% with respect to the composition of the elements of Group III (Al and Ga), and the composition ratio is Al_{0.2}Ga_{0.8}N. When the composition ratio of gallium element (Ga) is decreased to be smaller than this, the characteristics of Al_{y}Ga_{1-y}N become closer to the characteristics of AlN in FIG. 2, and the difference in the lattice constant between Al_{y}Ga_{1-y}N and GaN becomes larger. When the difference in the lattice constant becomes larger, defects and the like occur, and decrease in the crystallinity and deterioration of the characteristics of the semiconductor device 100 occur.

In regard to the semiconductor device of the present embodiment, in order to suppress the formation of an impurities (GaO) generated at the interface between the cap layer and the passivation layer 60, the composition ratio of the gallium element (Ga) in the cap layer is decreased to be smaller than the composition ratio of the gallium element (Ga) in the AlGaN layer, which is a barrier layer. Also, in order to adopt consistency in the lattice constant between AlGaN and GaN, an indium aluminum gallium nitride layer 40 containing indium element (In) is used.

Regarding the indium aluminum gallium nitride layer 40 of the semiconductor device of the present embodiment, an indium aluminum gallium nitride layer 40 having a composition ratio y of the gallium element (Ga) that is smaller than the composition ratio y of the gallium element (Ga) of the aluminum gallium nitride layer 30, is used. Since the composition ratio of the gallium element (Ga) of the aluminum gallium nitride layer 30 is about 80% with respect to the composition of the element of Group III (Al and Ga), the composition ratio of the gallium element (Ga) of the indium aluminum gallium nitride layer 40 is less than 80% with respect to the composition of the element of Group III (In, Al, and Ga).

When the composition ratio of the gallium element (Ga) in the cap layer of the semiconductor device of the present embodiment is decreased, and InₓAl_{y}Ga_{1-x-y}N that contains indium element (In) and has characteristics in the vicinity of the broken line, which is the value of the lattice constant of GaN, is used, a semiconductor device having satisfactory crystallinity with suppressed occurrence of an impurities (GaO) can be formed.

If the composition ratio of the gallium element (Ga) of the indium aluminum gallium nitride layer 40 is less than 80% with respect to the composition of the elements of Group III (In, Al, and Ga), the following Expression (1) is established.

1−x−y<0.8 Expression (1)

In regard to InₓAl_{y}Ga_{1-x-y}N having characteristics in the vicinity of the broken line in FIG. 2, Table 1 shows the values of the composition ratio x of the indium element (In) and the composition ratio y of the aluminum element (Al), which have been calculated from the gradients of the various sides of the triangle connecting the respective plots of GaN, AlN, and InN, by varying the composition ratio of Ga from 0.8 to 0.0 by an increment of 0.1.

TABLE 1

| In (x) | Al (y) | Ga (1 − x − y) |
|---|---|---|
| 0.18 | 0.82 | 0.00 |
| 0.16 | 0.74 | 0.10 |
| 0.14 | 0.66 | 0.20 |
| 0.13 | 0.57 | 0.30 |
| 0.11 | 0.49 | 0.40 |
| 0.09 | 0.41 | 0.50 |
| 0.07 | 0.33 | 0.60 |
| 0.05 | 0.25 | 0.70 |
| 0.04 | 0.16 | 0.80 |

In regard to the correlation between the composition ratio x of indium element (In) and the composition ratio y of aluminum element (Al), when the composition ratio x of the indium element (In) is approximately 22% with respect to the composition ratio y of the aluminum element (Al), the lattice constant of InₓAl_{y}Ga_{1-x-y}N is positioned on the broken line, and this lattice constant matches the lattice constant of the gallium nitride layer (GaN) as the first semiconductor layer. That is, the correlation between the composition ratio x of the indium element (In) and the composition ratio y of the aluminum element (Al) is represented by the following Expression (2).

x≈0.22y Expression (2)

In a case in which the composition ratio x of the indium element (In) is set to 22% of the composition ratio y of the aluminum element (Al), when the indium aluminum gallium nitride layer 40 is presented based on the composition ratio y, the composition becomes as follows: In_{0.22y}Al_{y}Ga_{1-1.22y}N (0≦y≦(1/1.22)).

A method for producing the semiconductor device 100 of the present embodiment will be explained below. In regard to the semiconductor device 100, GaN is subjected to crystal growth on a substrate 10 by a MOCVD (Metal Organic Chemical Vapor Deposition) method or the like, and a gallium nitride layer 20 is laminated on the substrate. The MOCVD method is a method of supplying an organic metal and a carrier gas onto the substrate 10, and causing epitaxial growth by causing a chemical reaction in the gas phase on a heated substrate.

After the gallium nitride layer 20 is laminated on the substrate 10, trimethylaluminum (TMA) and trimethylgallium (TMG), which are organic metal raw materials, and ammonia as are supplied together with a carrier gas (nitrogen or hydrogen) and reacted, and thereby an aluminum gallium nitride layer 30 is laminated on the gallium nitride layer 20.

After the aluminum gallium nitride layer 30 is laminated on the gallium nitride layer 20, similarly TMA, TMG, trimethylindium (TMI), ammonia gas, and a carrier gas are supplied and reacted, and thereby an indium aluminum gallium nitride layer 40 is laminated on the aluminum gallium nitride layer 30. The composition ratio between the indium element (In) and the aluminum element (Al) that are added at this time is represented by Expression (2).

However, such a lamination method according to a MOCVD method is only an example, and the present embodiment is not intended to be limited to the MOCVD method.

After the indium aluminum gallium nitride layer 40 is laminated, a source electrode 50, a gate electrode 51, and a drain electrode 52 are installed on the indium aluminum gallium nitride layer 40 by a heat treatment (alloy treatment).

Thereafter, a passivation layer 60 is laminated over the indium aluminum gallium nitride layer 40 and the various electrodes by a plasma-enhanced CVD (Plasma-enhanced Chemical Vapor Deposition) method or the like. However, the method for laminating the passivation layer 60 according to a plasma-enhanced CVD method is only an example, and the present embodiment is not intended to be limited to the plasma-enhanced CVD method.

As described above, in the semiconductor device 100 of the present embodiment, the impurities produced by bonding between the oxygen element (O) included in the passivation layer 60 and the gallium element (Ga) included in the cap layer is suppressed. Thereby, the semiconductor device 100 of the present embodiment exhibits suppressed current collapse or the like, and has an effect of suppressing deterioration of the characteristics of the semiconductor device and deterioration of the service life of the device.

### Second Embodiment

Across-sectional diagram of the semiconductor device 100 of a second embodiment is similar to FIG. 1.

The lattice constant of the indium aluminum gallium nitride layer 40 as a cap layer of the present embodiment matches the aluminum gallium nitride layer 30, which is a second semiconductor layer.

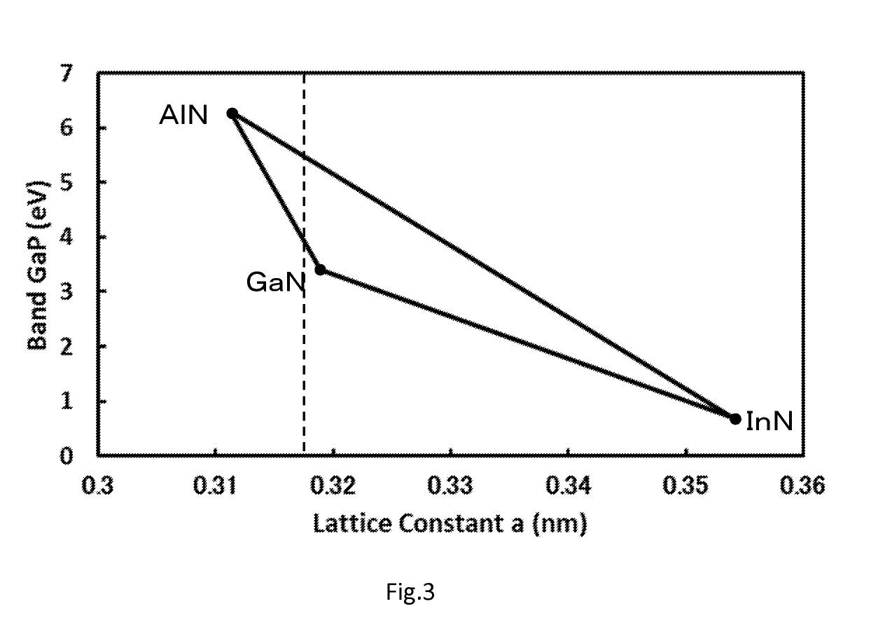

FIG. 3 is a correlation diagram between the lattice constant and the band gap of AlGaN, a nitride semiconductor. The broken line in the diagram represents the value of the lattice constant of AlGaN on the occasion in which the composition ratio y of aluminum element (Al) in the second semiconductor layer corresponds to a predetermined proportion.

Since the indium aluminum gallium nitride layer 40 (InₓAl_{y}Ga_{1-x-y}N) of the present embodiment is positioned on this broken line part, defects in the aluminum gallium nitride layer 30 as the second semiconductor layer and the indium aluminum gallium nitride layer 40 as the third semiconductor layer can be suppressed.

In regard to the indium aluminum gallium nitride layer 40, by making the composition ratio y of gallium element in the aluminum gallium nitride layer 30 small, impurities (GaO) produced by bonding between the oxygen element (O) included in the passivation layer 60 and the gallium element (Ga) included in the cap layer are suppressed. This composition ratio y is less than 80%, similarly to the first embodiment.

Furthermore, in the method for producing the semiconductor device 100 of the present embodiment, the amounts of trimethylaluminium and trimethylindium that are added upon the lamination of the indium aluminum gallium nitride layer 40 are changed from the amounts used in the first embodiment. It is necessary to add a larger amount of aluminum element (Al) compared to the case of the production method of the first embodiment. The other processes are similar to those of the first embodiment.

As described above, similarly to the first embodiment, the semiconductor device 100 of the present embodiment suppresses impurities that are produced by bonding between the oxygen element (O) included in the passivation layer 60 and the gallium element (Ga) included in the cap layer. Thereby, the semiconductor device 100 of the present embodiment exhibits suppressed current collapse or the like, and has an effect of suppressing deterioration of the characteristics of the semiconductor device and deterioration of the service life of the device.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a substrate;
a first nitride semiconductor layer formed on the substrate;
a second nitride semiconductor layer formed on the first nitride semiconductor layer and containing gallium element; and
a third nitride semiconductor layer formed on the second nitride semiconductor layer and containing indium element, aluminum element, and gallium element, the composition ratio of the gallium element in the third nitride semiconductor layer being a proportion smaller than the composition ratio of the gallium element in the second nitride semiconductor layer.

2. The semiconductor device according to claim 1, wherein the composition ratio of the gallium element in the third nitride semiconductor layer is less than 80% with respect to the composition of indium element, aluminum element, and gallium element.

3. The semiconductor device according to claim 1, wherein the third nitride semiconductor layer has lattice constant characteristics approximately identical to those of the first nitride semiconductor layer, based on the composition ratio of the indium element and the composition ratio of the aluminum element.

4. The semiconductor device according to claim 1, wherein the third nitride semiconductor layer has lattice constant characteristics approximately identical to those of the second nitride semiconductor layer, based on the composition ratio of the indium element and the composition ratio of the aluminum element.

5. The semiconductor device according to claim 1, wherein the composition ratio of the indium element in the third nitride semiconductor layer is about 22% with respect to the composition ratio of the aluminum element.

6. The semiconductor device according to claim 2, wherein the third nitride semiconductor layer has lattice constant characteristics approximately identical to those of the first nitride semiconductor layer, based on the composition ratio of the indium element and the composition ratio of the aluminum element.

7. The semiconductor device according to claim 2, wherein the third nitride semiconductor layer has lattice constant characteristics approximately identical to those of the second nitride semiconductor layer, based on the composition ratio of the indium element and the composition ratio of the aluminum element.

8. The semiconductor device according to claim 2, wherein the composition ratio of the indium element in the third nitride semiconductor layer is about 22% with respect to the composition ratio of the aluminum element.
